(19) United States
(12) Patent Application Publication
(10) Pub. No.: US 2009/0262492 A1
(43) Pub. Date: Oct. 22, 2009

(54) SUBMERSIBLE KEYBOARD

(75) Inventors: Bradley W. Whitchurch, Jacksonville, FL (US); David Vaillancourt, Bellevue, WA (US); Jack P. Corrao, II, San Diego, CA (US); Weijie Chen, Dong Guan (CN); Junnon Huang, Dong Guan (CN)

Correspondence Address: J. Andrew Mccarthy, Jr., 915 W. 2nd Ave., Windermere, FL, 34786, US

(73) Assignee: SEAL SHIELD, LLC, Jacksonville, FL (US)

(21) Appl. No.: 12/257,926

(22) Filed: Oct. 24, 2008

Related U.S. Application Data
(60) Provisional application No. 61/000,595, filed on Oct. 26, 2007.

(51) Int. Cl. H05K 7/00

(52) U.S. Cl. 361/679.08

(57) ABSTRACT

A waterproof, submersible computer keyboard can include true-type keys, a waterproof flexible internal keyboard switch membrane, a PCB sealed in a waterproof airtight compartment housing that is sealed in a manner preventing failure of the waterproof seal from temperature and pressure changes associated with cleaning, submersion and machine washing. The keyboard can further include a plurality of drain holes in the keyboard base for water drainage and non-corrosive components including stainless steel screws, aluminum stabilizers and a gold plated USB connector.

### FIELD OF THE INVENTION

The invention relates in general to a human interface device (“HID”) and, more particularly, to a waterproof, submersible keyboard.

### BACKGROUND OF THE INVENTION

Conventional HIDS, including keyboards, calculators, data entry terminals, remotes, cellular and wired telephones provide little or no protection against liquids, including, but not limited to, water, cleaning fluids, disinfectants, antimicrobial solutions and solvents, or to solid particles such as sand, dust or bone shards. In fact, occasional or prolonged exposure to or submersion in liquids may cause conventional HIDs to malfunction, and conventional HIDs are almost certainly destroyed by submersion in such liquids. These liquids are able to drain around the key system and enter a conventional HID, coming into contact with the electrical circuitry, e.g. the printed circuit board (“PCB”) or other electrical components of the HID and shorting out the circuits therein.

The ability of HIDs to resist liquids and solid particles is important for a number of reasons, including the fact that users occasionally accidentally spill liquids thereon or inadvertently submerse the HID by, for example, dropping it in water. Moreover, particularly in the healthcare industry with respect to HIDs and particularly keyboards, such HID should be disinfected and washed in a variety of ways, including, but not limited to, in an automatic dishwasher. Existing keyboards generally fail to withstand exposure to or submersion in antimicrobial solutions, abrasive automatic dishwashing cleaners, cleaning agents, bodily fluids, gels and other liquids. Such keyboards should also be able to withstand the temperature and pressure extremes encountered in an automatic dishwasher or through submersion.

To understand the complexity of the problem, it is important to realize that the keys of an HID, and particularly the keys of a keyboard, serve several functions. Such keys operate primarily to make switch contact, but it is also desirable that they provide the user with a snap-like tactile sensation or feedback, hereafter referred to as the tactile feedback signal, whereby the user is assured of successful switch operation. This tactile feedback signal is provided in three ways: (1) by providing a desirable amount of resistance to key actuation; (2) through “over-travel” of the keys; and (3) through a bottoming of the key at the end of the key stroke.

The switches within a keyboard or other HID employ a wide variety of devices, including, but not limited to, spring loaded assemblies and deformable dome spring elements, to provide this tactile feedback signal.

Thus, while for the foregoing reasons it is desirable to have an HID which is sealed against liquid penetration and is fully submersible and dishwasher safe. A diminished tactile feedback signal, which signal is necessary to inform the user of successful switch operation, is undesirable.

Healthcare industry studies have shown that keyboards are a primary source of cross contamination infections. A University of Arizona study found that the average keyboard contains 400 times more microbial bacteria than the average toilet seat. Studies have further shown that up to 25% of hospital keyboards harbor the antibiotic resistant bacteria, methicillin-resistant staphylococcus aureus (MRSA), which causes life threatening staphylococcus infections. Further, given the increasing prevalence of “super-bugs”, “super-flus”, particularly against the backdrop of global health scares such as Avian (bird) flu, the United States, as well as the rest of the world, is facing an infection problem of growing proportions.

With the increased incidence of antibiotic resistant bacteria such as MRSA, this problem has become a priority, especially in hospital and emergency care settings. More than 70% of the bacteria that cause hospital-acquired infections are resistant to at least one of the drugs most commonly used to treat those infections. MRSA alone now accounts for more than 60% of all hospital-acquired staphylococcus infections, while it accounted for only 2% of such infections in 1980. Since hospitals and emergency healthcare providers are generally an initial line of defense against the spread of serious illness, they must also be an initial priority when seeking to control the spread of germs, disease and infection.

The large number of patients obtaining hospital-acquired infections, or, more generically, healthcare-associated infections (collectively, “HAIs”), as well as the resulting deaths, serves to further confirm the serious and urgent nature of what is an undeniably global problem. According to the most recent statistics provided by the Centers for Disease Control and Prevention (CDC), in the United States alone, there are 4.5 HAIs for every 100 patient admissions, resulting in between 1.7 to more than 2 million HAIs per year. The overwhelming majority of HAIs [1.2 million] occur outside of the ICU, which is typically the primary focus of most infection control monitoring, thus suggesting that the actual incidents of HAIs is vastly underreported. HAIs alone cost up to $28 billion in additional healthcare costs to the United States each year. Perhaps the most sobering statistic is that over 103,000 Americans die every year as a direct result of an HAI, which now ranks as one of the top 10 killers of Americans.

Patients who have a HAI can expect an extension of their hospital stay. While some endure extended stays of up to thirty (30) days, other patients endure months or years of rehabilitation and treatment and may be left permanently disabled, as the result of an HAI. Patients acquiring a HAI, such as MRSA, often require additional surgeries and treatments which can, in and of themselves, result in disability or death. HAIs are not just limited to hospitals, but rather are a risk for anyone receiving treatment in a healthcare facility such as nursing homes, dialysis center, or doctor's office. In fact, HAIs can also infect otherwise healthy people in the community at large, with symptoms that generally appear as skin infections. The bottom line is that the occurrence of HAIs is on the rise and needs to be controlled so as to stop the pain, suffering and death they cause, in addition to the exorbitant cost to the United States healthcare system.

Keyboard surfaces have been shown to be a major harbor for bacteria and other microbes. Despite the fact that HAIs are a top 10 killer of Americans, heretofore little could be done to address the problem of keyboards as a primary cross contamination point.

Infection control is not the only reason that it is desirable for keyboards utilized with medical equipment to be resistant to liquids, fully submersible, and able to withstand the temperature and pressure extremes associated with an automatic dishwasher. A problem that frequently arises in ultrasound applications is that the user applies an electrically conductive gel to the patient before inputting data. Frequently, the gel is not completely removed from the user's hands, leaving a residue on the keyboard, the buildup of which, over time, diminishes performance by interfering with switch operation and negatively impacting the tactile feedback signal.

Regrettably, conventional keyboards are not well suited at addressing this problem because most cannot be repeatedly cleaned or disinfected, and none are capable of withstanding the temperature and pressure extremes associated with an automatic dishwasher or long periods of submersion.

In addition to the need, in the healthcare industry, for keyboards to withstand exposure to and submersion in disinfectants and other cleaning solutions, as well as frequent washings using an automatic dishwasher or other similarly harsh cleaning methods, keyboards must be able to withstand exposure to bodily fluids and bone shards, particularly in hospital ORs and ERs.

Despite the demonstrated demand for spill-proof, submersion-proof and dishwasher safe HIDs, as well as a critical need for HIDs which can be disinfected and washed repeatedly, no keyboard currently exists that can be repeatedly cleaned and disinfected, as well as be fully submersed in water or placed in a dishwasher without malfunctioning or being damaged or destroyed.

The various existing approaches to providing some resistance of HIDs, namely keyboards, to liquids and solid particles can be gleaned from certain U.S. Patents and U.S. Patent Publications.

For example, in U.S. Patent Publication No. 2003/0222800, entitled, “Keyboard Assemblies,” a liquid resistant barrier is located between the keys and the switch membrane and circuit board, which liquid resistant barrier, the applicant claims, provides protection against spilled aqueous liquids and ethanol/water combinations for 30 seconds at 22° C. Molded integrally with this liquid resistant barrier are a plurality of deformable spring members, one deformable spring member for each key, which resist movement of the keys. This invention accomplishes increased resistance to spilled liquids, the applicant claims, by diverting liquids and by draining or channeling them away from internal keyboard components.

The disadvantages of this approach include the fact that it is not submersible for extended periods of time, it can not be washed in an automatic dishwasher, and it does not meet IP68 standards. Moreover, because a plurality of spring members are molded integrally with the liquid resistant barrier, bacteria, viruses, fungi, dirt, oil, dust and other grime will accumulate between the keys and the liquid resistant barrier, so that when a user depresses a key, its smooth movement will be inhibited in that it will stick, bind, or remain in the depressed position for an extended period of time before returning to the static position. This negatively affects switch operation, thereby increasing the likelihood of accidental input and restricting the pace at which the user may input data.

Another example of the shortcomings of the prior art is U.S. Pat. No. 6,664,901, entitled, “Keyboard Input Device.” This patent describes a film substrate with a plurality of conducting patterns, which conducting patterns each have a pair of contact parts. The film substrate is provided with a moisture resistant insulating overcoat, which exposes the contact parts. Elastic spring members are bonded at their base to the insulating overcoat by means of an adhesive. The top of each elastic spring member is affixed to a key-top.

This design protects only the film substrate, not the circuit board. Further, it does not meet IP 68 standards, it provides no protection against submersion or cleaning in an automatic dishwasher, and it permits the accumulation of bacteria, viruses, fungi, dirt, oil, dust and other grime between the key-tops and the film substrate, inhibiting smooth movement of the key-tops such that they will stick, bind, or remain in the depressed position for an extended period of time before returning to the static position.

U.S. Pat. No. 5,612,692, entitled, “Full Travel, Sealed, Fully Backlighted Keyboard,” discloses a sealed, full travel keyboard. One limitation of this invention is that it must be separated from the underlying printed circuit board to permit complete washing and sterilization of the keys. An additional limitation is inherent in the fact that keys are individually sealed by means of a skirt on each key, which skirt receives sidewalls which are molded into the keyboard panel. The small crevice between the skirt and the sidewalls provides the opportunity for the accumulation of bacteria, viruses, fungi, dirt, oil, dust and other grime therebetween, so that when a user depresses a key, its smooth movement will be inhibited and it will stick, bind, or remain in the depressed position for an extended period of time before returning to the static position. Removal of each individual key would be required to clean the crevice between the key skirt and the sidewalls of the keyboard panel. This design does not meet IP68 specifications and does not permit full submersion or cleaning in an automatic dishwasher.

Yet another example of the shortcomings of the prior art can be found in U.S. Pat. No. 5,340,955, entitled, “Illuminated and Moisture-Sealed Switch Panel Assembly.” This patent discloses an environmentally sealed key switch assembly having a plurality of individual keys. The patent further discloses an elastomeric sheet with a plurality of holes, which holes correspond to the individual keys and which stretch around each key in order to provide the environmental seal. The shortcomings of this invention include the fact that it is not fully submersible, it does not meet IP68 standards, it is not dishwasher safe, and it has a diminished tactile feedback signal due to the interference by the elastomeric sheet with the downward pressure exerted by the user and the spring-like return force. Moreover, because the keys are interconnected by the elastomeric sheet, depressing one key moves adjacent keys, again diminishing the tactile feedback signal.

Finally, U.S. Pat. No. 4,634,818, entitled, “Switches and Keyboards,” discloses a combined cover and membrane of deformable material bearing a plurality of open-circuit conductors which membrane is attached to a printed circuit board by means of a peripheral lip. Limitations of this invention include the fact that it does not meet IP68 standards, it is not fully submersible, and it is not dishwasher safe. Additionally, the tactile feedback signal is diminished because of the short travel of the keys and because the absence of a spring-like member under each key results in less of a snap-like tactile feedback signal.

These and other prior art approaches have many shortcomings. Individually and collectively, these include a less than optimal tactile feedback signal, lack of protection from submersion, lack of protection from the temperature and pressure extremes associated with an automatic dishwasher, and the presence of small crevices which allow the accumulation of bacteria, viruses, fungi, dirt, oil, dust and other grime such that they may not be sterilized without being submersed in disinfectant or washed in an automatic dishwasher. The result of such accumulation is the inhibition of the smooth movement of a key in that it will stick, bind, or remain in the depressed position for an extended period of time before returning to the static position. The lack of smooth movement of keys negatively affects switch operation, increases the likelihood of accidental input and restricts the pace at which the user may input data.

Accordingly, the art fails to teach or suggest a fully submersible HID which meets IP68 standards, and which can withstand the temperature and pressure extremes associated with washing in an automatic dishwasher. Such an HID needs to be easily cleaned through a variety of methods including, inter alia, using an automatic dishwasher, so as to prevent the accumulation of bacteria, viruses, fungi, dirt, oil, dust and other grime that can inhibit the smooth movement of the keys without diminishing the optimality of its tactile feedback signal. Importantly, the art fails to teach such an HID that does not compromise on overall robustness, reliability, manufacturability or performance.

### SUMMARY OF THE INVENTION

In the present invention, the above limitations are overcome and objects and advantages achieved by use of a waterproof flexible internal switch membrane (“waterproof membrane”) and a waterproof PCB housing. The waterproof membrane, in one form thereof, is comprised of two flexible polypropylene films on which conductive patterns are printed in opposed relation with a polycarbonate spacer barrier therebetween. The polycarbonate spacer barrier includes a plurality of holes therethrough that are located at positions corresponding to contact points on the respective polypropylene films. The conductive pattern is printed with electrically functional ink, in this case ink pigmented with silver, though those skilled in the art will appreciate that other conductive materials such as graphite, gold, nickel, or copper may be used. The perimeter of the polypropylene films are bonded using a high temperature adhesive. The contact points are positioned on each of the polypropylene films at the location of the holes in the polycarbonate spacer barrier such that the application of force at the opposed contact points causes a switch to close. The switches are connected via the printed conductive pattern, which terminate at the tongue of the waterproof membrane.

The conductive lines in the tongue of the waterproof membrane connect to the electrical circuitry, or PCB, which PCB is completely sealed in a waterproof, airtight housing (“PCB Housing”). The waterproof housing encapsulates and protects the PCB from submersion, and also protects the connection between the PCB and the waterproof membrane. The waterproof housing is comprised of two halves and two perimeter gaskets.

Aspects of the invention include a testing port on one half of the PCB Housing, which port is a small hole which can be used to test the housing's ability to maintain compressed air pressure, and which is sealed after testing.

In another aspect of the invention, an array of deformable dome spring elements are positioned on top of the contact points of the waterproof membrane and below the key caps. In this way, the deformable dome spring elements provide a biasing force against the individual key caps. When an associated key cap is pressed downwardly, it collapses and causes the contact points on the opposing polypropylene sheets to connect, thereby closing a switch.

In a further aspect of the invention, each individual key is snap fit into the outer shell to permit easy removal and replacement, and to allow the user to disable a key by removing the associated key cap, removing the deformable dome spring element situated therebelow and replacing the key cap.

In another aspect of the invention, the base contains a plurality of drain holes to facilitate water drainage.

In another aspect of the invention, a stabilizer bar is provided in conjunction with the space bar, the shift key caps and the enter key cap to prevent pivoting of those key caps about an axis perpendicular to their longest dimension.

In another aspect of the invention, non-corrosive components, including stainless steel screws, aluminum stabilizer bars and a gold plated USB connector, are utilized, to protect the invention from damage due to frequent submersions or exposure to corrosive substances.

Aspects of the invention further include a completely submersible and washable HID that can be cleaned and disinfected with common chemicals. The invention can be completely submerged in an automatic dishwasher or sink to ensure bacteria, viruses, fungi and other infections material will be eliminated, as well as to remove any solid particles such as sand, dust, dirt, bone shards or buildup or residue from cleaning products and disinfectants. In addition to the foregoing, the instant invention comprises a fully submersible waterproof keyboard that meets IP 68 standards and which has true-type keys which provide an optimal tactile feedback signal.

Aspects of the present invention relate to waterproof components for an HID, specifically a keyboard, that is machine washable and capable of withstanding the rigors of cleaning and sterilization, such as cleaning wipes, spray disinfectants, bleach, steam, water, high temperatures and pressure changes, even when placed in an automatic dishwashing or sterilization machine. This waterproof keyboard can be utilized in the fight against HAIs, especially in a hospital, ER and other medical settings where keyboards and mice routinely come in contact with a variety of individuals, germs and bacteria, thus they must be regularly sterilized or replaced.

The submersible keyboard can be cleaned, disinfected and sterilized, even under high temperature and pressure conditions, without compromising the function of the keyboard. The keyboard can go straight from the dishwasher to the desktop, while still wet, and function without limitation. Although the invention has a myriad of applications for the healthcare, consumer and corporate markets, the invention was initially created to combat and control the spread of germs, disease and infection, especially in hospital and other healthcare settings.

### BRIEF DESCRIPTION OF THE DRAWINGS

The objects, advantages and features of this invention will be more clearly appreciated from the following detailed description when taken in conjunction with the accompanying drawings, in which:

FIG. 1 is an exploded perspective view of the submersible keyboard disclosed herein.

FIG. 2 is an exploded perspective view illustrating the PCB Housing according to aspects of the present invention.

FIG. 3 is a plan view of the waterproof membrane according to aspects of the present invention.

FIG. 4 is a perspective view of a deformable dome spring element according to aspects of the present invention.

FIG. 5 is a perspective view of the PCB Housing according to aspects of the present invention.

FIG. 6 is a perspective view of the keyboard shell base illustrating drain holes according to aspects of the present invention.

FIG. 7 is a perspective view of the keyboard illustrating a stabilizer bar according to aspects of the present invention.

### DETAILED DESCRIPTION OF THE PREFERRED EMBODIMENT

According to aspects of the present invention, a waterproof, dishwasher safe HID, specifically a keyboard, is disclosed. The keyboard can be easily washed, disinfected and even sterilized under high heat and high pressure situations, yet it maintains an optimal tactile feedback signal. The submersible keyboard meets IP68 standards and can be fully submerged in water, as well as sterilized in an automatic dishwasher, without affecting the look, function or operation of the true-type keyboard. One unique feature of the design allows the waterproof keyboard to go directly and immediately from a sink or automatic dishwasher to the desktop, while still wet, and be ready for use without the function of the keyboard being compromised or affected in anyway.

The result is a waterproof keyboard that, on the outside, appears no different and operates no differently than any other standard keyboard. However, on the inside, the submersible keyboard is designed and sealed internally so as to withstand the rigors associated with common cleaning and sterilization protocols, such as exposure to cleaning solutions and other liquids, temperature changes, and pressure changes, without affecting the appearance, form or function thereof.

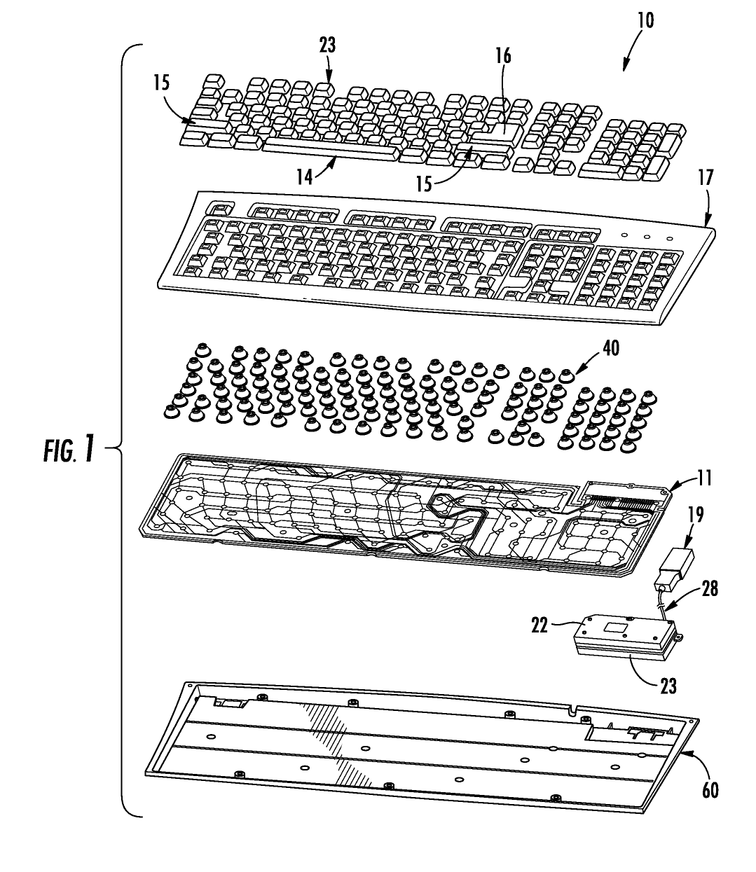

With reference now to the drawings, and more particularly, to FIGS. 1-3 thereof, a submersible keyboard assembly 10 according to aspects of the present invention is described as including a waterproof membrane 11 that allows the user's keystrokes to be transmitted to the PCB 12 without compromising the waterproof nature of the keyboard. These features provide isolation to all conducting patterns as well as to the PCB.

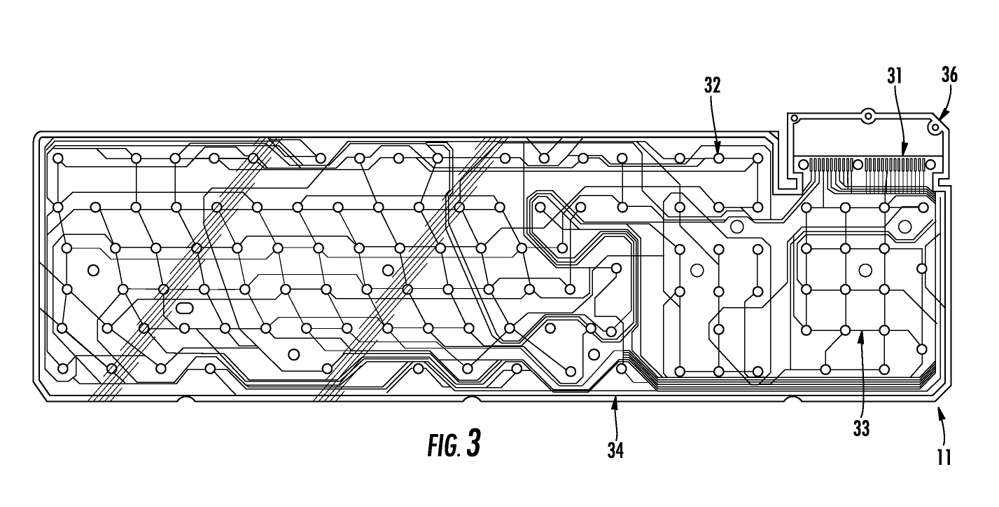

Referring now to FIG. 3, the waterproof membrane 11 according to aspects of the present invention can provide the flexibility, durability and reliability needed to stand up to the rigors that face a keyboard used in a high volume area with multiple users (e.g. hospitals, ER's, dialysis centers, etc.) while still maintaining the waterproof nature of the keyboard so it can be easily cleaned and disinfected.

In the preferred embodiment, the waterproof membrane is comprised of two flexible films on which conductive patterns 33 are printed in opposed relation with a spacer barrier therebetween. One skilled in the art would readily appreciate that the flexible films and the spacer barrier can be constructed of a variety of non-conducting materials, in the preferred embodiment the flexible films are made of polypropylene, while the spacer barrier is constructed of polycarbonate. The polycarbonate spacer barrier includes a plurality of holes therethrough that are located at positions corresponding to contact points 32 on the respective polypropylene films. The conductive patterns 33 are printed with electrically functional ink. One skilled in the art would readily appreciate that the electrically functional ink is ink pigmented with a conductive material such as graphite, gold, silver, nickel or copper, in the preferred embodiment, the ink is pigmented with silver. The perimeter 34 of the polypropylene films are bonded using a high temperature adhesive. The contact points 32 are positioned on each of the polypropylene films at the location of the holes in the polycarbonate spacer barrier such that the application of force at the opposed contact points 32 causes a switch to close. The switches are connected via the conductive patterns 33, which terminate at the tongue 31 of the waterproof membrane.

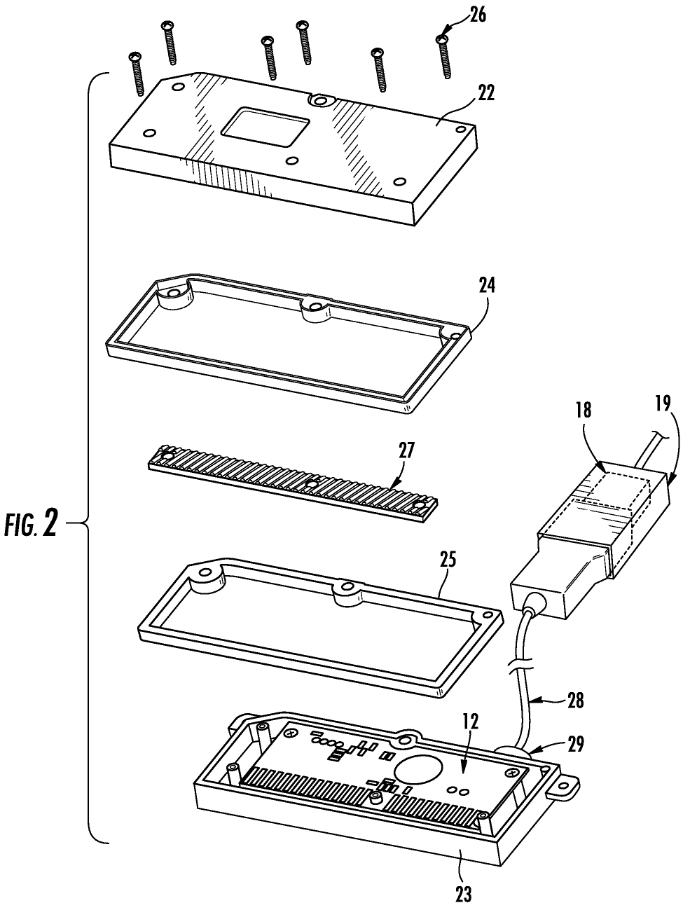

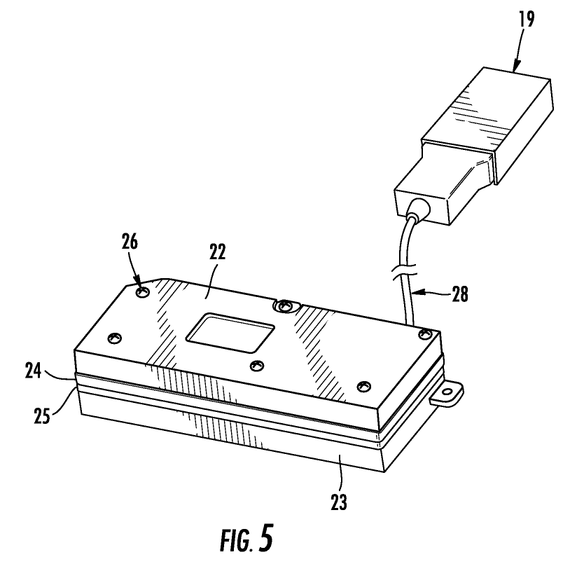

The conductive lines 33 in the tongue 34 of the waterproof membrane connect to the electrical circuitry, specifically, the PCB 12, which PCB 12 is completely sealed in the PCB Housing shown in FIGS. 2 and 5. In the typical HID, the PCB is unenclosed or is, at the most, covered by a liquid resistant barrier. This design leaves the PCB vulnerable to water intrusion, which would typically result in immediate failure of the HID.

To solve the vulnerability of the exposed PCB, in this invention, the PCB 12 is entirely enclosed in the PCB Housing. In the preferred embodiment, the PCB Housing is comprised of two pieces, a top cover 22, and a bottom cover 23. The PCB Housing serves a number of functions, including: (1) offering complete protection of the PCB 12 from exposure to water, even when the HID is completely submersed; (2) providing a waterproof connection to the flexible waterproof membrane; and (3) providing a waterproof connection to a computer. In the preferred embodiment, the two covers of the waterproof PCB Housing are made of polypropylene and polycarbonate (e.g. similar to Lexan® material). The top cover 22 and bottom cover 23 are then be joined together and sealed with a pair of uniquely designed silicone gaskets, a top gasket 24 and a bottom gasket 25, along with a sealant such as that manufactured by 3M or Owens-Corning, that form a compression fit. The top gasket 24 and bottom gasket 25 are designed so that they fit around the perimeter of the top cover 22 and bottom cover 23 respectively to form a compression fit. The top cover 22, bottom cover 23, top gasket 24 and bottom gasket 25 are joined together by means of 6 stainless steel screws 26. One skilled in the art will readily appreciate that a variety of fasteners could be used to accomplish the same task. Further note that the top cover 22 and bottom cover 23 can also be joined together by using adhesives or ultrasonic welding techniques as well.

In the preferred embodiment, the top cover 22 is translucent, so that status indicator lights on the PCB can be seen therethrough.

The conductive lines 33 in the tongue 31 of the waterproof membrane connect to the PCB 12 between the top gasket 24 and bottom gasket 25, and the outer perimeter 36 of the tongue 34 is shaped like the top gasket 24 and bottom gasket 25 so that it fits therebetween such that the proper orientation between the waterproof membrane and the PCB 12 is maintained. A rectangular shaped silicone strip 27 is located inside the PCB housing to provide a biasing force against the conductive lines 33 in the tongue 31 of the waterproof membrane such that a proper connection is made between the waterproof membrane and the PCB 12.

In the preferred embodiment, the means of communication between the keyboard and the computer is via a USB cable. The PCB 12 connects to the computer via a USB cable 28, which protrudes through the PCB Housing. Though a USB cable is used here, those skilled in the art will appreciate that connection to the computer can be made in a variety of ways, including wirelessly. In the preferred embodiment, a waterproof seal is made between the PCB Housing and the USB cable 28 by means of a compression fit rubber grommet 29.

The compression fit rubber grommet 29 ensures that water cannot get through the seal, even if the waterproof PCB housing is opened. The combination of materials and design allows the waterproof seal to expand and contract in a manner that prevents water intrusion, even under the pressure and temperature extremes associated with common cleaning protocols (e.g. submersion in water, sterilization or cleaning in a dishwasher).

The PCB housing can include a testing port so each keyboard can be tested to make sure it is waterproof before it leaves the manufacturing plant. Each PCB housing can be tested to make sure it is waterproof by injecting compressed air into the testing port while the keyboard is fully submerged in water. After testing, the testing port is sealed by means of a silicone plug.

Although one skilled in the art will appreciate that a variety of methods could be utilized to apply letters, titles, legends or other symbols to the key caps 23, including pad printing, engraving, embossing, double shot molding, film clips, transfer decals and screen printing, the key caps 23 on the preferred embodiment are printed using a laser etching process to prevent fading from repeated washing. By utilizing this process, the lettering can be actually knurled into the plastic, after which it is oxidized. The oxidation process produces lettering having a white appearance, which, unlike typical keyboard lettering, cannot be scratched or removed from the key cap 23 since it is essentially “burned” into the plastic. The result is that there is no way to remove the lettering from the instant invention without destroying the key cap 23 itself, thus repeated washings will not fade the lettering.

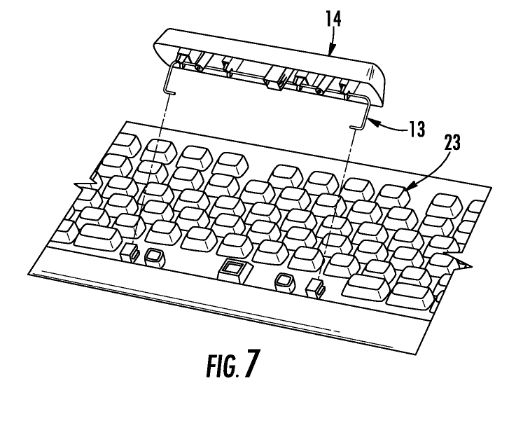

In the preferred embodiment, as depicted in FIG. 7, a stabilizer bar 13 is provided in conjunction with the space bar 14, the shift key caps 15 and the enter key cap 16 to prevent pivoting of those key caps about an axis perpendicular to their longest dimension.

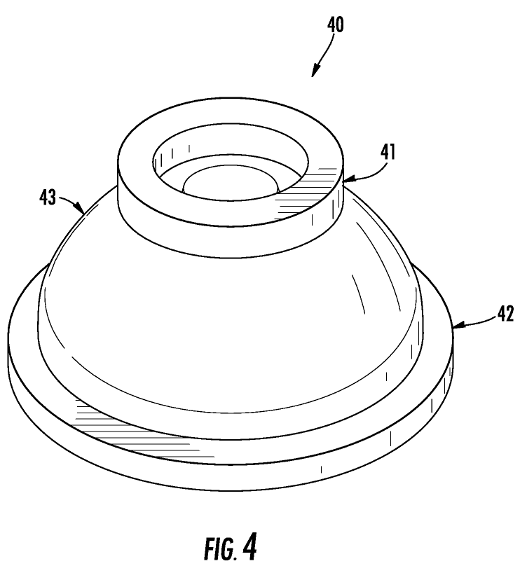

With reference now to FIG. 4, in the preferred embodiment, disposed below the each key cap 23 is a semi-spherically shaped deformable dome spring element 40, which deformable dome spring elements 40 provide a biasing force against individual key caps 23. That is, the individual key caps 23 are biased away from the waterproof membrane by means of the deformable dome spring elements 40.

At the top of each deformable dome spring element 40 is a cylindrical protrusion 41. Each of the deformable dome spring elements 40 includes an annular mounting flange 42 formed at the lower part thereof.

When a key cap 23 is depressed, the cylindrical protrusion 41 presses downwardly equally and symmetrically on the dome 43 so that the dome 43 flexes or deforms downwardly uniformly around its entire cross-section. By deforming downwardly, the cylindrical protrusion 41 at the top of the deformable dome spring element 40 transfers the force applied to the key cap 23 to the opposed contact points 32 located therebelow, causing a switch to close.

The deformable dome spring elements 40 are made of a flexible silicone having a memory which causes it to return to its normal shape after it has been deformed and collapses, returning the key cap 23 to its static position. One skilled in the art will appreciate that the size and thickness of the deformable dome spring element 40 can be adjusted to any selected force/displacement curve, providing the desired tactile feedback signal.

In the preferred embodiment, the keys are true-type keys, meaning that the keystrokes of the instant invention are virtually identical to the keystrokes of convention keyboards, allowing the user to utilize the keyboard without having to modify typing style or position.

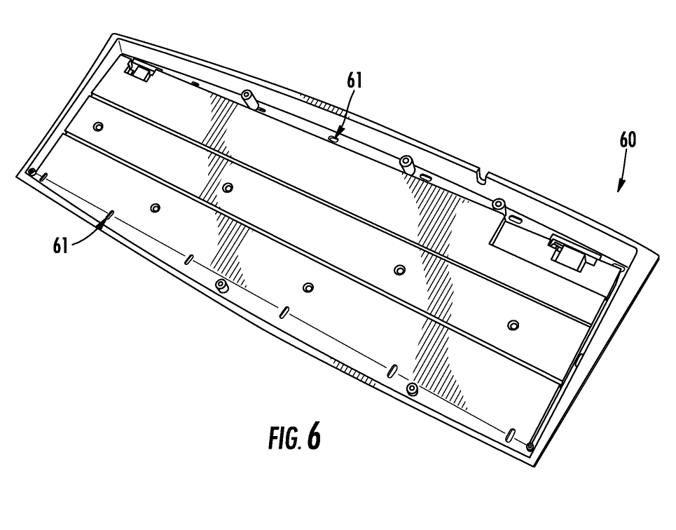

Referring next to FIG. 6, aspects of the present invention include multiple drain holes 61 in the keyboard shell base 60, which keyboard shell base 60 attaches to the keyboard shell cover 17. The drain holes 61 are specifically designed to allow for proper drainage in a rapid fashion, thus preventing water build up from the washing processes and reducing the time the keyboard is out of use during washing. The drain holes 61 in the preferred embodiment are oval shaped, though other shapes could be used.

According to one aspect of the invention, the keyboard is constructed with non-corrosive components, including stainless steel screws and aluminum stabilizer bars 13, as well as a gold plated USB connector 18, all of which prevents rust or degradation from exposure to water and other elements.

The individual components utilized to create the present invention have been shown to maintain there electromechanical functionality after multiple exposures to a variety of sterilization procedures, including those utilized in the hospital environment. All of the subject components have shown the ability to maintain their electromechanical operation after 2,000 exposures to washing machine sterilization, wherein the components are exposed to cleaning chemicals and high temperatures (135 degrees Fahrenheit) for a period of 60 minutes.

In the preferred embodiment, water intrusion in the USB connector 18 is prevented through the use of a silicone waterproof cap 19.

In as much as the preceding disclosure presents the the various embodiments and it is intended to enable one skilled in the pertinent art to carry it out, it is apparent that structures and methods incorporating modifications and variations will be obvious to those skilled in the art. As such, it should not be construed to be limited thereby but include such aforementioned obvious variations within the scope of the appended claims.

What is claimed is:

1. A human interface device (HID) assembly comprising:
a waterproof membrane having circuitry therein forming at least one switch for the HID and further having an external portion having exposed circuitry on the waterproof membrane during pre-assembly;
a board having electrical circuitry; and
a printed circuit board (PCB) Housing for encapsulating the board and the exposed circuitry on the waterproof membrane, wherein the encapsulation of the board connects the electrical circuitry of the board with the exposed circuitry on the waterproof membrane.

2. The HID assembly as recited in claim 1, wherein the HID is a keyboard.

3. The keyboard as recited in claim 2, wherein said board having electrical circuitry is a PCB which is separately encapsulated with the externally exposed circuitry on the waterproof membrane from a remaining portion of the waterproof membrane.

4. The keyboard as recited in claim 2, further comprising a plurality of key caps and a plurality of deformable dome spring elements placed above the waterproof membrane, one deformable dome spring element being associated with each of said key caps.

5. The keyboard as recited in claim 4, wherein said key caps are printed using a laser etching process.

6. The keyboard as recited in claim 4, further comprising stabilizer bars associated with the larger key caps.

7. The keyboard as recited in claim 6, wherein said stabilizer bars are made of aluminum.

8. The keyboard as recited in claim 2, further comprising a keyboard shell base and keyboard shell cover.

9. The keyboard as recited in claim 8, wherein the keyboard shell base and keyboard shell cover and a plurality of key caps are made of plastic embedded with silver ions.

10. The keyboard as recited in claim 8, wherein said keyboard shell base has a plurality of drain holes.

11. The keyboard as recited in claim 10, wherein said drain holes are oval shaped.

12. The keyboard as recited in claim 2, further comprising stainless steel screws and a gold plated USB connector.

13. The keyboard as recited in claim 8, wherein the keyboard shell base or the keyboard shell cover forms a portion of the PCB Housing encapsulating the board.

14. The keyboard as recited in claim 2, wherein the exposed circuitry on the waterproof membrane is formed on a tongue of the waterproof membrane.

15. The keyboard as recited in claim 14, wherein the encapsulation of the board biases a plurality of conductive runners on the tongue of the waterproof membrane to a corresponding plurality of conductive runners on the board.

16. A waterproof keyboard assembly comprising:
a waterproof membrane having internal circuitry therein forming a plurality of switches sealed within the waterproof membrane and used for a plurality of keys of the waterproof keyboard and further having an external portion having exposed circuitry coupled to the internal circuitry on the waterproof membrane;
a keyboard encoder board having electrical circuitry thereon; and
a printed circuit board (PCB) Housing for encapsulating the keyboard encoder board and the exposed circuitry on the waterproof membrane, wherein the encapsulating encapsulates the exposed circuitry and further biases the exposed circuitry to connect with electrical circuitry on the keyboard encoder board.

17. The keyboard as recited in claim 16, further comprising a keyboard shell base and keyboard shell cover, wherein the keyboard encoder board is encapsulated in a waterproof airtight compartment housing that is sealed in a manner preventing failure of a waterproof seal from temperature and pressure changes associated with cleaning, submersion and machine washing.

18. The waterproof keyboard as recited in claim 17, wherein the keyboard shell base forms a portion of the PCB Housing encapsulating the board

19. The keyboard as recited in claim 16, wherein the exposed circuitry on the waterproof membrane is formed on a tongue of the waterproof membrane.

20. The keyboard as recited in claim 19, wherein the encapsulation of the board biases a plurality of conductive runners on the tongue of the waterproof membrane to a corresponding plurality of conductive runners on the board.
